(19) United States
(12) Patent Application Publication
(10) Pub. No.: US 2002/0175693 A1
(43) Pub. Date: Nov. 28, 2002

(54) Material property detection system and method

(75) Inventors: Tatiana N. Starr, San Diego, CA (US); Douglas N. Paulson, Del Mar, CA (US)

Correspondence Address: FOLEY & LARDNER, 402 WEST BROADWAY, 23RD FLOOR, SAN DIEGO, CA, 92101

(73) Assignee: Tristan Technologies, Inc.

(21) Appl. No.: 10/155,096

(22) Filed: May 23, 2002

Related U.S. Application Data
(60) Provisional application No. 60/293,744, filed on May 24, 2001.

(51) Int. Cl. G01R 27/08

(52) U.S. Cl. 324/702

(57) ABSTRACT

According to the disclosed embodiment of the present invention, a system and method for detecting properties of a material are provided using a detection apparatus including a pair of reflecting surfaces, and directing electromagnetic radiation into the apparatus. The radiation is focused through a slab of material having a negative refractive index to a subwavelength spot. Electromagnetic radiation is detected to determine characteristics of a sample under test.

### RELATED APPLICATIONS

This present application claims priority to U.S. provisional patent application entitled MATERIAL PROPERTY DETECTION SYSTEM AND METHOD, assigned Serial No. 60/293,744 and filed on May 24, 2001.

### BACKGROUND OF THE INVENTION

1. Field of the Invention

The present invention relates to a system and method, which may be used for detecting materials properties, such as surface resistance and the like in materials such as conductors and semiconductors, dielectric constant and losses in dielectrics.

2. Background Art

There have been a variety of different types and kinds of devices and methods for detecting surface properties of materials such as superconductors and normal conductors. For example, reference may be made to U.S. Pat. Nos. 5,239,269 and 5,440,238.

Also, reference may be made to the following published articles:

Experimental Verification of a Negative Index of Refraction, R. A. Shelby, D. R. Smith, S. Schultz, Reports, Science, Vol. 292, Apr. 6, 2001.

Precise Dielectric Measurements At 35 GHz Using An Open Microwave Resonator, R. G., Jones, B.Sc., M.Sc. (Tech.), Ph.D., PROC. IEE, Vol. 123, No.4, April 1976;

An Automated 60 GHz Open Resonator System For Precision Dielectric Measurement, M. N. Afsar, Fellow, IEEE, Xiaohui Li, and Hua Chi, IEEE Transactions on Microwave Theory and Techniques, Vol. 38, No. 12, December 1990;

Confocal Resonators For Measuring the Surface Resistance of High-Temperature Superconducting Films, J. S. Martens, V. M. Hietala, D. S. Ginley, and T. E. Zipperian, G. K. G. Honenwarter, Appl. Phys. Lett. 58 (2), Jun. 3, 1991;

MM-Wave Confocal Resonators for Vertical Structure Profiling in Semiconducting and Superconducting Materials, J. S. Martens, L. Lee, K. Char, R. Withers, and D. Zhang, 1993 IEEE MTT-S Digest;

Characterization of Delamination and Disbonding in Stratified Dielectric Composites by Millimeter Wave Imaging; S. Bakhtiari, N. Gopalsami, and A. C. Raptis, Materials Evaluation/April 1995;

Measurement of Dielectrics at 100 GHz with an Open Resonator Connected to a Network Analyzer, T. M. Hirvonen, P. Vainikainen, A. Lozowski, and A. V. Raisanen, IEEE Transactions on Instrumentation and Measurement, Vol 45, No.4, August 1996;

Evanescent Electromagnetics: A Novel, Super-Resolution, and Non-Intrusive, Imaging Technique for Biological Applications, M. Tabib-Azar, S. Bumrerraj, J. L. Katz, and S. H. You, Biomedical Microdevices 2:1, 73-80, 1999;

A New 60 GHz Open-Resonator Technique for Precision Permittivity and Loss-Tangent Measurement, M. N. Afsar, Hanyi Ding, and K. Tourshan, IEEE Transactions and Instrumentation and Measurement, Vol 48, No.2, April 1999;

A Cryogenic Microwave Scanning Near-Field Probe: Application to Study of High-Tc Superconductors, A. F. Lann, M. Abu-Teir, M. Golosovsky, D. Davidov, S. Djordjevic, N. Bontemps, L. F. Cohen, Review of Scientific Instruments, Volume 70, Number 11, November 1999;

Dielectric Constant and Thickness Measurement of Low-K thin film by EMP, Z. Wang, Zhi-Xun Shen, M. Kelly, Xiao-Dong Xiang, J. Wetzel, American Physical Society Meeting, 2000;

Quantitative Imaging of Dielectric Permittivity and Tunability with a near-field scanning microwave microscope, D. E. Steinhauer, F. C. Wellstood, S. M. Anlage, C. Canedy, R. Ramesh, A. Stanishevsky, J. Melngailis, Review of Scientific Instruments, Vol. 71, (No. 7), AIP, July 2000;

Negative Refractive Index in Left-Handed Materials, D. R. Smith and N. Kroll, Physical Review Letters, Volume 85, Number 14, Oct. 2, 2000;

Negative Refraction Makes a Perfect Lens, J. B. Pendry, Physical Review Letters, Volume 85, Number 18, Oct. 30, 2000;

Magnetic Permeability Imaging of Metals With a Scanning Near-Field Microwave Microscope, L. Sheng-Chiang, C. P. Vlahacos, B. J. Feenstra, A. Schwartz, D. E. Steinhauer, F. C. Wellstood, S. M. Anlage, Applies Physics Letters, Vol. 77, (No. 26), AIP, Dec. 25, 2000;

Novel Optical Material Could Mean Sharper Lithography, J. Mullins, IEEE Spectrum, January 2001;

All of the foregoing patents and publications are incorporated herein by reference as if fully set forth herein.

As mentioned in U.S. Pat. No. 5,239,269, techniques have been employed for determining and imaging super conductor surface resistance. The patented technique includes a modified Gaussian Confocal resonator structure with the sample under test being disposed remotely from the radiating mirror by a distance equal to one-half the radius of curvature of the radiating mirror. The surface resistance is determined by imaging reflected microwaves to reveal anomalies due to surface impurities, non-stoichiometry in the surface of the superconductor. However, the spatial resolution may not be entirely satisfactory for some applications, since the imaged spot can not be substantially smaller than the wavelength.

The U.S. Pat. No. 5,239,269 employs a confocal resonator structure wherein the sample under test is disposed at a distance of half the standard radius of curvature of the concave mirror. The purpose is to provide the testing of a remotely disposed sample under superconducting conditions, while the testing equipment itself can remain at room temperature.

However, it is desirable to have a system and a method to more precisely and accurately detect smaller defects. Such a system and method should have high spatial resolution and not just to a spot defined by the wavelength.

### DESCRIPTION OF THE DRAWINGS

FIG. 1 is a diagrammatic view of one embodiment of a materials property detection system as disclosed herein.

### DETAILED DESCRIPTION

According to the disclosed embodiment of the present invention, a system and method for detecting properties of a material are provided using a detection apparatus including a pair of reflecting surfaces, and directing electromagnetic radiation into the apparatus. The radiation is focused through a slab material having a negative refractive index to a subwavelength spot. Electromagnetic radiation is detected to determine characteristics of a sample under test.

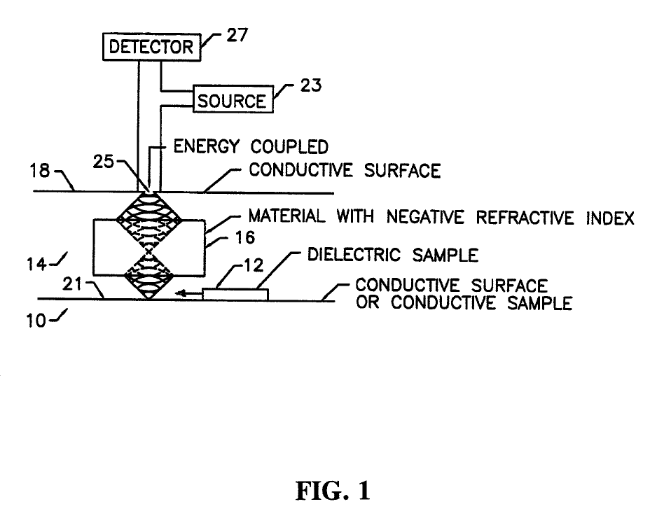

Referring now to FIG. 1, there is shown an embodiment of a surface property detection system 10. The system 10 is a detection apparatus with subwavelength focusing capabilities for detecting properties in a dielectric sample 12 under test. The system 10 employs a detection apparatus generally indicated at 14, where the energy inside the apparatus may be focused to a subwavelength spot size. The focusing may be done by a slab 16 of material which has negative refractive index, and performs as a perfect lens. This system may be used, for example, for materials characterization where dielectric samples may be placed inside the detection apparatus 14 and conductive samples may serve as a part of the apparatus. Focusing to a subwavelength provides improved spatial resolution for materials testing for some applications. Thus, the disclosed system is precise and accurate, and can detect small defects or other surface abnormalities.

According to an embodiment of the present invention, the detection apparatus 14 may, for example, include two parallel conductive plates or reflective surfaces 18 and 21. It is to be understood that the reflecting surfaces 18 and 21′ may cooperate and function as a open structure resonator, however, it is not essential that resonance occurs. A source 23 generates electromagnetic radiation in the range of between about 10⁹ Hz and about 10¹² Hz, or in other frequency ranges such as optical frequency range by modifying suitably the detection apparatus 14 to include suitable reflectors (not shown) in place of the conductive plates. The energy may be coupled through an opening 25 in the resonator 14. For example, the opening 25 may be in the form of a small hole provided in one of the surfaces such as the surface 18 (or some other manner). Alternatively, there may be a device (not shown) for coupling energy into the apparatus 14.

According to an embodiment of the present invention, the slab 16 of appropriate dimensions with negative refractive index may be placed inside the apparatus 14 and can focus the electromagnetic radiation to a spot less than a wavelength size. According to one example of the invention, the slab 16 is composed of a material known as a left handed material, which includes an array of conductive split rings and rods and which is described in greater detail in the foregoing publications as hereinabove incorporated by reference. The material has both negative permeability and negative permittivity, and serves as an ideal perfect lens, thereby providing the ability to focus electromagnetic radiation to a subwavelength spot. It should be understood that other materials having a negative refraction index may become apparent to those skilled in the art.

The electromagnetic radiation may be focused on the sample 12 under test. The electromagnetic radiation may be reflected from a second conductive plane if a dielectric sample is measured. The microwaves may be reflected from a conductive sample if conductive samples are measured. In accordance with the illustrated embodiment, a device 27 detects electromagnetic radiation reflected from the detection apparatus 14 (or transmitted through the apparatus 14). Electromagnetic and structural characteristics of materials and image may be determined from reflected (or transmitted) radiation.

While particular embodiments of the present invention have been disclosed, it is to be understood that various different modifications and combinations are possible and are contemplated within the true spirit and scope of the appended claims. There is no intention, therefore, of limitations to the exact abstract and disclosure herein presented.

What is claimed is:

1. A system for detecting properties of a sample under test, comprising:
a detection apparatus including a pair of reflecting surfaces;
means for generating electromagnetic radiation directed into said apparatus;
a slab of material having a negative refractive index disposed inside said apparatus for focusing the radiation to a subwavelength spot; and
means for detecting electromagnetic radiation via said apparatus to determine characteristics of the material under test.

2. A system according to claim 1, wherein said slab of material is composed of left handed material.

3. A system according to claim 2, wherein said slab of material has both negative permeability and negative permittivity characteristics.

4. A system according to claim 1, wherein said reflecting surfaces include a pair of spaced apart conductive surfaces, and said slab is disposed therebetween.

5. A system according to claim 4, wherein one of said surfaces includes an opening for receiving electromagnetic radiation from said means for generating said electromagnetic radiation.

6. A system according to claim 4, wherein said means for generating electromagnetic radiation generates it in the range of about 10⁹ Hz and about 10¹² Hz.

7. A system according to claim 4, wherein said sample under test is disposed inside said apparatus.

8. A system according to claim 1, wherein said means for detecting helps determine electromagnetic and structural characteristics of materials and images of the material under test.

9. A method for detecting properties of a sample under test, comprising:
using a detection apparatus having a pair of reflecting surfaces;
directing electromagnetic radiation into said apparatus;
focusing the radiation through a slab of material having a negative refractive index to a subwavelength spot; and
detecting electromagnetic radiation via said detection apparatus to determine characteristics of the material under test.

10. A method according to claim 9, wherein said slab of material is composed of left handed material.

11. A method according to claim 10, wherein said slab of material has both negative permeability and negative permittivity characteristics.

12. A method according to claim 9, wherein said resonator includes a pair of spaced apart conductive surfaces, and further including disposing said slab therebetween.

13. A method according to claim 12, wherein one of said surfaces includes an opening, further including receiving electromagnetic radiation through said opening and into the interior of said apparatus.

14. A method according to claim 12, wherein said generating electromagnetic radiation is generated in the range of about 10⁹ Hz and about 10¹² Hz.

15. A method according to claim 12, further including disposing said sample under test inside said apparatus.

16. A method according to claim 9, wherein said detecting includes determining electromagnetic and structural characteristics of materials and images of the sample under test.
